(19) United States
(12) Patent Application Publication
(10) Pub. No.: US 2017/0017146 A1
(43) Pub. Date: Jan. 19, 2017

(54) PROCESS FOR REMOVING CONTAMINATION ON RUTHENIUM SURFACE

(71) Applicant: APPLIED Materials, Inc., Santa Clara, CA (US)

(72) Inventor: Jerry Dustin Leonhard, Kalispell, MT (US)

(73) Assignee: APPLIED MATERIALS, INC., Santa Clara, CA (US)

(21) Appl. No.: 14/798,311

(22) Filed: Jul. 13, 2015

(51) Int. Cl. G03F 1/22; B08B 7/00; B08B 3/04; B08B 3/08

(52) U.S. Cl. CPC G03F 1/22; B08B 3/08; B08B 7/0035; B08B 3/04

(57) ABSTRACT

A method for pretreating an EUVL photomask having an exposed ruthenium surface includes subjecting the photomask to surface treatment in an oxidizing and reducing environment. Another method for pretreating an EUVL photomask having an exposed ruthenium surface includes subjecting the photomask to surface treatment in an oxidizing and reducing environment, and cleaning the photomask with a cleaning solution.

### BACKGROUND

In extreme ultra-violet lithography (EUVL), an EUVL lithography reflection photomask in used. In contrast with a conventional lithography transmission photomask (compare FIGS. 5A and 5B), EUVL photomasks use a multi-layer stack to maximize reflective power of the short (13.5 nm) wavelength projecting a pattern onto the workpiece.

To maintain the highest level of reflectivity, the EUVL photomask is periodically cleaned to remove surface contamination. Aggressive cleaning can damage the surface and shorten the lifetime of the mask. However, insufficient cleaning can allow contamination to build and decrease the reflectivity in the EUVL photomask.

Therefore, there exists a need for an improved process for cleaning an EUVL photomask to optimize the lifetime of the mask.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In accordance with one embodiment of the present disclosure, a method for pretreating an EUVL photomask having an exposed ruthenium surface is provided. The method includes subjecting the photomask to surface treatment in an oxidizing and reducing environment.

In accordance with another embodiment of the present disclosure, a method for cleaning an EUVL photomask having an exposed ruthenium surface is provided. The method includes subjecting the photomask to surface treatment in an oxidizing and reducing environment, and cleaning the photomask with a cleaning solution.

In any of the embodiments described herein, subjecting the photomask to an oxidizing and reducing environment may include treatment with water vapor plasma.

In any of the embodiments described herein, subjecting the photomask to an oxidizing and reducing environment may include treatment with hydroxyl OH* and hydrogen radicals H*.

In any of the embodiments described herein, the surface treatment may oxidize carbon on the surface on the photomask.

In any of the embodiments described herein, the surface treatment may reduce the exposed ruthenium layer.

In any of the embodiments described herein, the cleaning solution may include ammonium hydroxide, hydrogen peroxide, and deionized water.

### DESCRIPTION OF THE DRAWINGS

The foregoing aspects and many of the attendant advantages of this disclosure will become more readily appreciated by reference to the following detailed description, when taken in conjunction with the accompanying drawings, wherein:

FIG. 1 is an exemplary EUVL reflection photomask blank including multiple layers of different materials, in accordance with embodiments of the present disclosure;

FIG. 2 is a fabricated EUVL reflection photomask showing exposed capping layer, in accordance with embodiments of the present disclosure;

FIG. 3 is a comparative graph showing Ru composition and oxidative state of the capping layer on the EUVL photomask of FIG. 2, as deposited, post carbon removal, and post clean using a previously developed carbon removal technology;

FIG. 4 is a comparative graph showing Ru composition and oxidative state of the capping layer on the EUVL photomask of FIG. 2, as deposited, post carbon removal, and post clean in accordance with embodiments of the present disclosure;

FIG. 5A is a previously developed conventional lithography transmission photomask showing absorption; and

FIG. 5B is an EUVL reflection photomask showing reflection.

### DETAILED DESCRIPTION

The present disclosure relates to methods for cleaning extreme ultra-violet lithography (EUVL) photomasks.

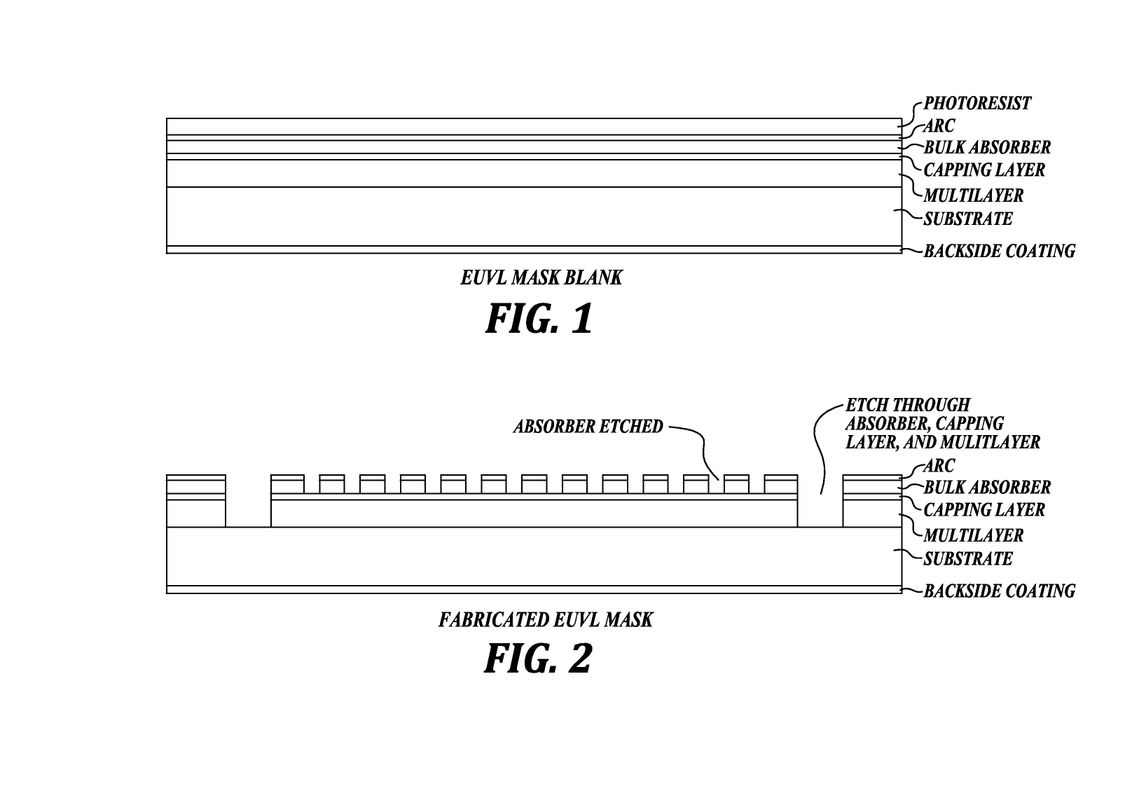

In contrast with convention lithography transmission photomasks, EUVL photomasks are reflection photomasks. Referring to FIG. 1, an exemplary EUVL reflection photomask 20 may include multiple layers of different materials. The layers include a backside coating layer 22, a substrate 24, a Bragg reflector 26 including multiple layers, a capping layer 28, an absorber layer 30, an anti-reflective coating layer 32, and a photoresist layer 34. Referring to FIG. 2, when fabricated, the capping layer 28 may be exposed on the EUVL photomask.

Ruthenium is typically used as the capping layer 28. In one non-limiting example, the ruthenium capping layer has a thickness of 2.5 nm. One drawback of a ruthenium capping layer, is its tendency to oxidize quickly.

The most common contamination on an EUVL photomask is carbon. The carbon layer grows on the exposed surface of the mask as it is exposed to air over time. In addition, other process-induced contaminations on mask surfaces may include residual photoresist, metalorganic compounds, and sub-micrometer particles during patterning. The most common way to remove carbon from the surface is to oxidize the surface. However, such oxidation for carbon removal also oxidizes the ruthenium capping surface of the EUVL photomask to the various oxidative states of RuO₂, RuO₃, and RuO₄.

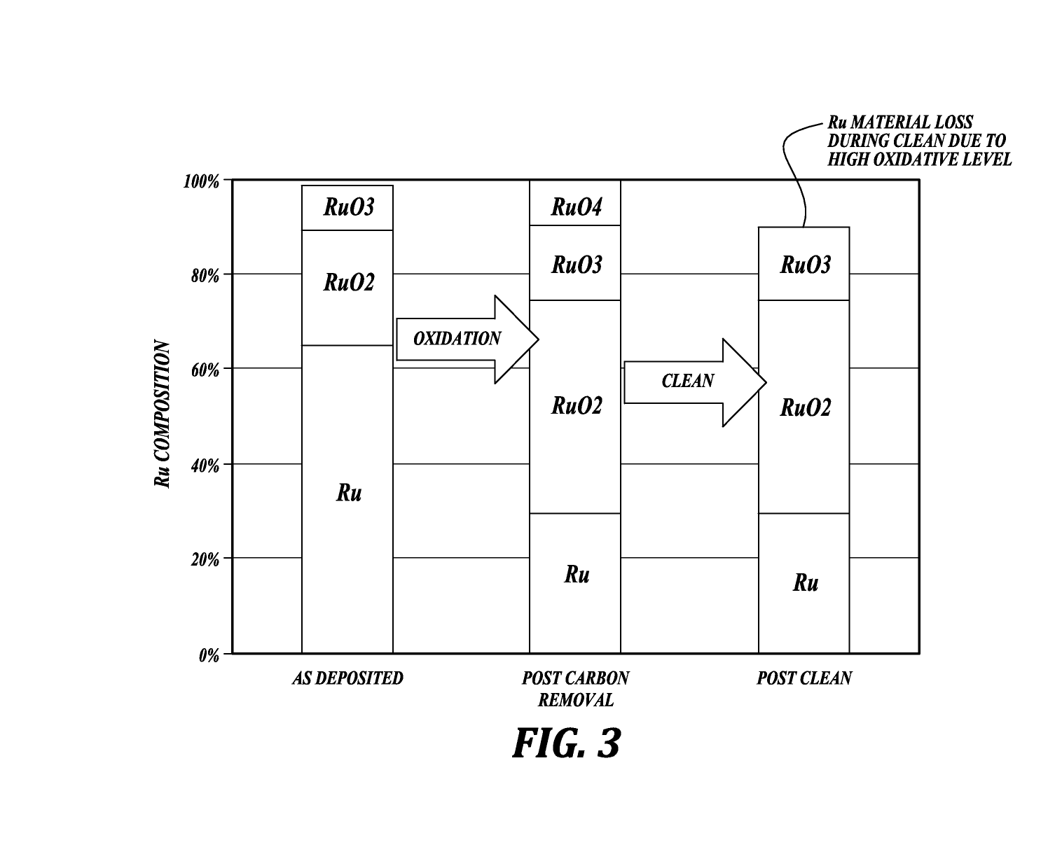

The higher oxidative states of ruthenium have higher etch rates in conventional mask cleaning chemistry causing loss of the total ruthenium thickness and reducing the lifespan of the EUVL photomask. As can be seen in FIG. 3, RuO₄ material is lost from the capping layer during the clean. The formation of oxides and increase in surface roughness as a result to material loss can negatively impact the reflectivity of the ruthenium capping layer.

In accordance with one embodiment of the present disclosure, the EUVL photomask is pre-treated in a reducing and oxidizing environment prior to cleaning Such treatment has the effect of oxidizing carbon on the surface of the EUVL photomask, while reducing the ruthenium surface to maintain lower oxidative states on the ruthenium surface.

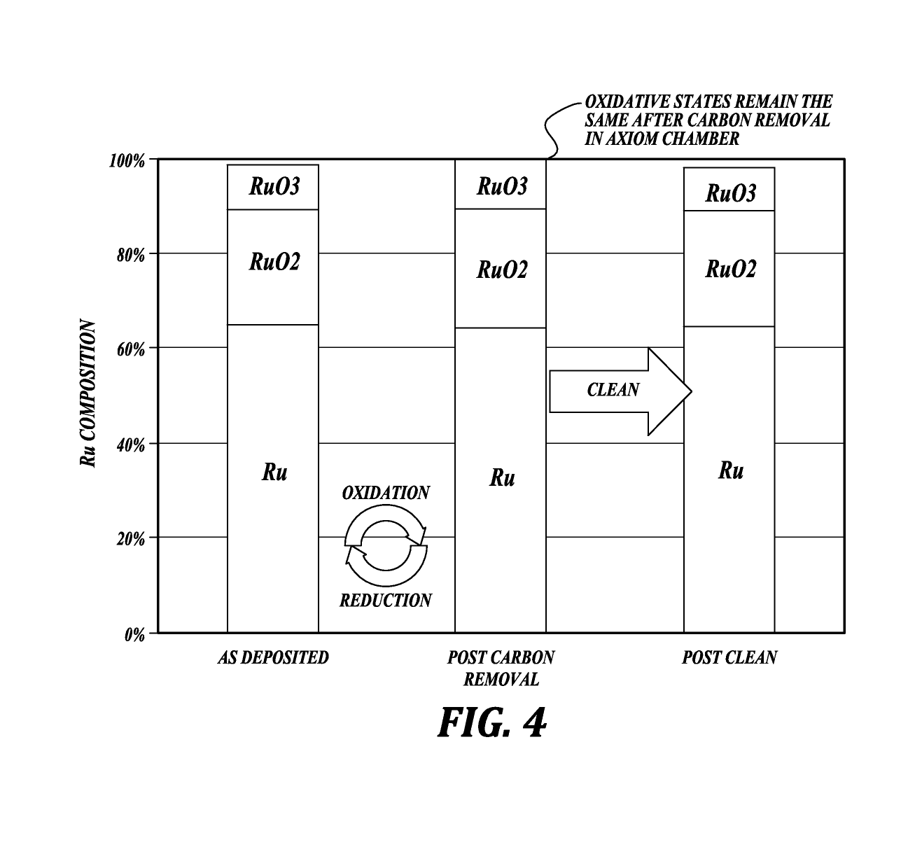

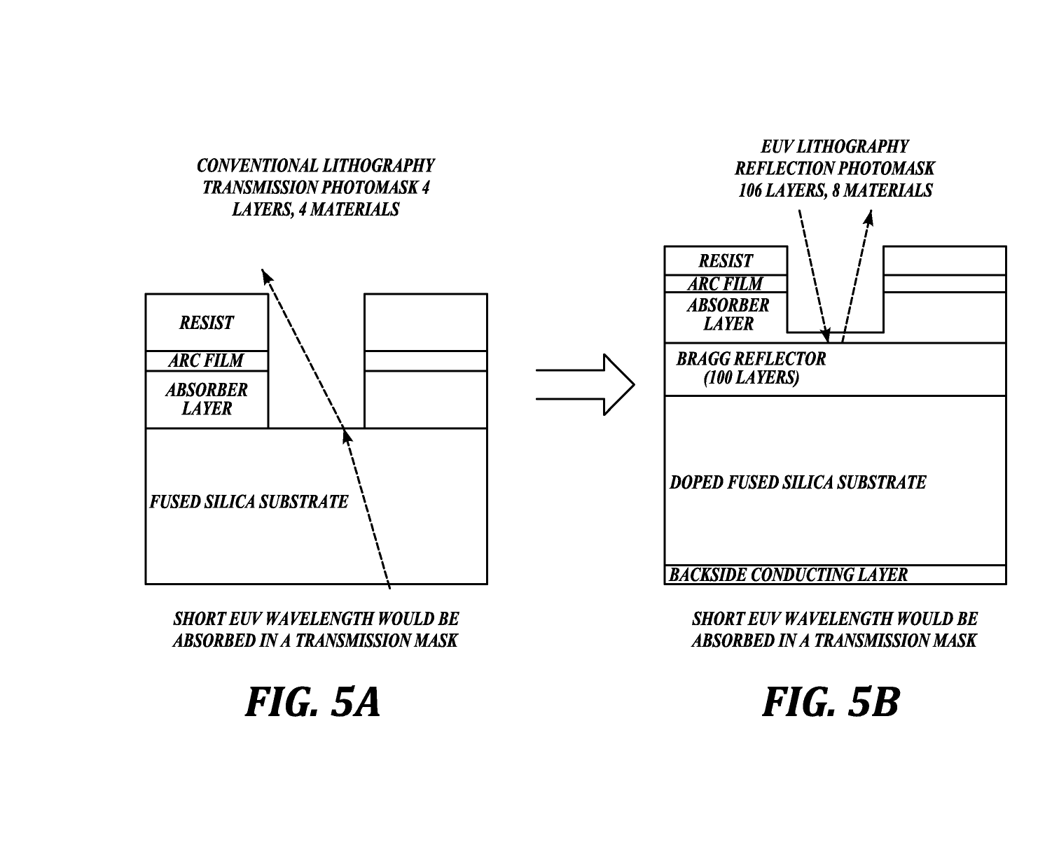

In one embodiment of the present disclosure, the EUVL photomask is pre-treated using a water vapor plasma prior to cleaning The treatment uses OH* and H* radicals to produce both a reducing and oxidizing environment. The oxidizing nature of the plasma removes the carbon contamination, while the competing reducing reaction maintains the ruthenium layer oxidative state. As can be seen in FIG. 4, the ruthenium material oxidative state of RuO3 remains the same after carbon removal.

After such treatment, the EUVL photomask can be cleaned using an SCI cleaning solution, which may include ammonium hydroxide, hydrogen peroxide, and de-ionized water. Other cleaning solutions are also within the scope of the present disclosure.

In accordance with embodiments of the present disclosure, oxide reduction can be achieved at a lower temperature using water plasma to reduce the metal oxide and also remove carbon from the seed layer surface. The hydrogen plasma includes H* radicals that can be used to uniformly reduce oxides and clean the seed layer surface in the feature.

### EXAMPLE

An exemplary EUVL reflection photomask includes 106 layers of eight different materials. The layers include a backside coating having a thickness of about 70 nm, a substrate having a thickness of about 6.35 mm, a Bragg reflector multilayer having 100 layers and a total thickness of about 275nm, a capping layer of about 2.5 nm, a bulk absorber having a thickness of about 55 nm, an anti-reflective coating layer having a thickness of about 15 nm, and a photoresist layer having a thickness of about 100 nm.

While illustrative embodiments have been illustrated and described, it will be appreciated that various changes can be made therein without departing from the spirit and scope of the disclosure.

The embodiments of the invention in which an exclusive property or privilege is claimed are defined as follows:

1. A method for pretreating an EUVL photomask having an exposed ruthenium surface, the method comprising:
subjecting the photomask to surface treatment in an oxidizing and reducing environment.

2. The method of claim 1, wherein subjecting the photomask to an oxidizing and reducing environment includes treatment with water vapor plasma.

3. The method of claim 1, wherein subjecting the photomask to an oxidizing and reducing environment includes treatment with hydroxyl OH* and hydrogen radicals H*.

4. The method of claim 1, wherein the surface treatment oxidizes carbon on the surface on the photomask.

5. The method of claim 1, wherein the surface treatment reduces the exposed ruthenium layer.

6. A method for cleaning an EUVL photomask having an exposed ruthenium surface, the method comprising:
(a) subjecting the photomask to surface treatment in an oxidizing and reducing environment; and
(b) cleaning the photomask with a cleaning solution.

7. The method of claim 1, wherein subjecting the photomask to an oxidizing and reducing environment includes treatment with water vapor plasma.

8. The method of claim 1, wherein subjecting the photomask to an oxidizing and reducing environment includes treatment with hydroxyl OH* and hydrogen radicals H*.

9. The method of claim 1, wherein the surface treatment oxidizes carbon on the surface on the photomask.

10. The method of claim 1, wherein the surface treatment reduces the exposed ruthenium layer.

11. The method of claim 1, wherein the cleaning solution includes ammonium hydroxide, hydrogen peroxide, and deionized water.
